(19) United States
(12) Patent Application Publication
(10) Pub. No.: US 2015/0356395 A1
(43) Pub. Date: Dec. 10, 2015

(54) Transponder Layer and Method for Producing Same

(71) Applicant: Smartrac IP B.V., Amsterdam (NL)

(72) Inventors: Martin Haring, Germering (DE); Stephan Dorn, Stuttgart (DE); Frank Kriebel, Lichtenberg (DE); Carsten Nieland, Gotha (DE)

(21) Appl. No.: 14/414,182

(22) PCT Filed: Jul. 12, 2013
(86) PCT No.: PCT/EP2013/002075

§ 371 Date: Jun. 12, 2015

(30) Foreign Application Priority Data
Jul. 13, 2012 (DE) 10 2012 212 332.6

(51) Int. Cl. G06K 19/077; H01L 23/00

(52) U.S. Cl. CPC G06K 19/07754; G06K 19/07722; G06K 19/07743; H01L 24/83

(57) ABSTRACT

The invention relates to a transponder layer (30), in particular for producing a laminate structure, for example being embodied as a chip card, having an antenna substrate (31), which, on an antenna side (38), is equipped with an antenna (33) formed from a wire conductor (32) as well as with a chip (41), and which, on the antenna side, has terminal conductors for connecting the chip to the wire conductor of the antenna, in such a manner that the chip is arranged adjacently to terminal ends (34, 35) of the wire conductor, and in such a manner that both the terminal ends of the wire conductor and chip terminals (39, 40), which are arranged on a contact side of a semiconductor body of the chip, said contact side facing towards the antenna substrate, are contacted with the terminal conductors. Furthermore, the invention relates to a laminate inlay for a laminate structure that is formed from multiple laminate layers, having such a transponder layer, to a chip card having such a laminate inlay, and to a method for producing such a transponder layer.

The present invention relates to a transponder layer, in particular for producing a laminate structure, for example being embodied as a chip card, having an antenna substrate, which, on an antenna side, is equipped with an antenna formed from a wire conductor as well as with a chip, and which, on the antenna side, has terminal conductors for connecting the chip to the wire conductor of the antenna, in such a manner that the chip is arranged adjacently to terminal ends of the wire conductor, and in such a manner that both the terminal ends of the wire conductor and chip terminals, which are arranged on a contact side of a semiconductor body of the chip, the contact side facing towards the antenna substrate, are contacted with the terminal conductors.

Furthermore, the invention relates to a laminate inlay for a laminate structure that is formed from multiple laminate layers, having such a transponder layer, to a chip card having such a laminate inlay, and to a method for producing such a transponder layer.

In particular when producing noncontact chip cards, it is known, for making it easier to contact the chip as well as for achieving a mechanical protection for the chip, to arrange the chip in a housing on a contact carrier, wherein the contact carrier forms a chip module together with the chip that is accommodated in the housing. On its contact surface that is embodied by the contact carrier, the chip module has module contact surfaces which are larger than the terminal faces of the chip, and which make it easier to contact the chip with the terminal ends of the antenna.

In comparison to the dimensions of the semiconductor body of the chip, the chip module has external dimensions that are considerably larger. In particular, the height of the chip module is considerably larger than the height of the actual chip, such that arranging a chip module in a laminate structure already demands a corresponding number of laminate layers. In known cards that have a laminate structure, on a regular basis, a laminate layer is therefore already required for accommodating the contact carrier of the chip module, the contact carrier being equipped with the larger terminal faces, and a second laminate layer is required in order to accommodate the housing in the laminate structure, the housing enclosing the semiconductor body of the chip.

If it is assumed that on a regular basis at least one further laminate layer is in each case necessary for covering the antenna of the antenna substrate as well as for covering the chip module, with the known chip cards that are constructed as a laminate structure, a minimum number of four laminate layers is the result, to which laminate layers further external laminate layers might be added, the external layers, as visible layers, being essential for the external design of the chip cards.

The present invention is based on the object to allow for the production of a chip card with the smallest possible number of laminate layers.

In order to attain this object, a transponder layer in accordance with the invention has the features of claim 1, a laminate inlay in accordance with the invention has the features of claim 9, a chip card in accordance with the invention has the features of claim 13 and the method in accordance with the invention, in a first variant, has the features of claim 16, in a second variant, it has the features of claim 21 and, in a third variant, it has the features of claim 22.

The transponder layer in accordance with the invention has an antenna substrate, which, on an antenna side, is equipped with an antenna formed from a wire conductor as well as with a chip, and which, on the antenna side, has terminal conductors for connecting the chip to the wire conductor of the antenna. The chip is arranged adjacently to the terminal ends of the wire conductor, wherein both the terminal ends of the wire conductor and chip terminals, which are arranged on a contact side of the semiconductor body of the chip, the contact side facing towards the antenna substrate, are contacted with the terminal conductors.

The transponder layer that is embodied in accordance with the invention allows for arrangement of the chip on one and the same substrate as the antenna, omitting a housing that accommodates the chip, wherein the chip and the terminal ends of the wire conductor of the antenna can substantially be arranged in one plane and wherein the terminal ends of the wire conductor that accommodate the chip between each other—subject to corresponding mechanical properties of the wire conductor—form a structure that acts in a mechanically supporting or stiffening way in the direct environment of the chip. In this way, the chip is not only arranged on the antenna side of the antenna substrate such that it protrudes beyond the cross-section of the terminal ends only marginally, thus allowing for a particularly small constructional height of the antenna substrate or of the transponder layer, but the chip is moreover also accommodated between the terminal ends of the wire conductor in a protected way.

Thus, in the transponder layer in accordance with the invention, even though a housing of a chip module for accommodating the semiconductor body of the chip is omitted, the semiconductor body of the chip is in particular protected from an alternating bending stress, which occurs, for example, when using a chip card having the transponder layer, or corresponding dynamic loads are at least partially absorbed by the terminal ends of the wire conductor, the terminal ends accommodating the chip between each other.

Moreover, the transponder layer in accordance with the invention allows for a secure contacting between the chip and the terminal ends of the wire conductor, due to the terminal conductors which are arranged on the antenna side, and which can have a large surface extension in comparison to the chip terminals. Here, the chip does not have to be arranged on a contact substrate that is independent from the antenna substrate, as it is the case in a chip module, in order to provide terminal faces that are larger in comparison to the chip terminals, for contacting with the terminal ends of the antenna.

The transponder layer in accordance with the invention, even though a chip module is omitted, allows for secure contacting between the chip and the antenna in that terminal conductors are provided on the antenna substrate, which allow for both a connection to the terminal ends of the antenna and a connection to the chip terminals of the chip.

In a preferred embodiment, the chip is arranged between the terminal ends of the wire conductor, such that accommodating the chip in a way that is as compact as possible is allowed for, wherein the terminal ends of the wire conductor are arranged on both sides.

In a first embodiment, the terminal conductors for connecting the chip to the wire conductor of the antenna are embodied as contact pads and are arranged on the antenna side in such a manner that the contact pads, for being contacted with the antenna, have an antenna contact portion having an antenna contact side facing towards the antenna side and, for being contacted with the chip, have a chip contact portion that is opposite to the antenna contact side and faces away from the antenna side.

In this embodiment, owing to the fact that contacting with the terminal ends of the antenna and with the chip terminals has been effected on opposite sides of the terminal conductors, namely on the antenna contact side and on the chip contact side, the terminal conductors that are arranged on the antenna side of the antenna substrate are arranged between the chip terminals and the terminal ends. For this reason, a transponder layer can be produced starting from an antenna substrate, which has only one wire conductor that is arranged or laid on the antenna substrate for forming the antenna.

A particularly good and extensive contact between the contact pads and the terminal ends of the wire conductor of the antenna becomes possible if the contact pads, for being contacted with the antenna, are embodied in such a way as to fit tightly against the cross-sectional outline of the wire conductor with their antenna contact side.

A particularly simple application, on the antenna side of the antenna substrate, of the terminal conductors that are embodied as contact pads, the antenna contact sides simultaneously being arranged on the terminal ends of the wire conductor, becomes possible if the contact pads, with their chip contact side, are arranged on a carrier substrate and if the chip terminals, for contacting the chip with the contact pads, extend through the carrier substrate, such that the contact pads, due to being arranged on a common carrier substrate, can be handled in a simple way and can be placed at precise positions.

In a further preferred embodiment, the terminal conductors for connecting the chip to the wire conductor of the antenna are embodied as contact pads and are arranged in the antenna substrate in such a manner that, with a contact side, which serves both for contacting with the antenna and for contacting with the chip, they are arranged at the surface of the antenna side of the antenna substrate. Thus, it is possible, for producing the transponder layer, to use an antenna substrate, which can already be equipped with contact pads before the wire conductor of the antenna is arranged on the antenna side of the antenna substrate, without the contact pads influencing the height of the antenna substrate.

In particular if the contact pads are embodied as packings, which fill substrate recesses in the antenna substrate, the contact pads can have a volume of material, which, if the material that is used for the packings, is selected correspondingly or suitably, simultaneously provides the connection material that is required for contacting between the terminal ends of the wire conductor and the contact pads or between the chip terminals and the contact pads. In this manner, a separate feeding of soldering material for producing a connection between the terminal ends of the wire conductor or between the chip terminals and the contact pads can be omitted for instance.

Handling the contact pads or arranging the contact pads in the substrate recesses of the antenna substrate can considerably be simplified if the packings, which serve for forming the contact pads, are arranged on a carrier substrate, which is arranged on a bottom side of the antenna substrate, in such a manner that contact sides that are formed by surfaces of the packings are arranged at the surface of the antenna side of the antenna substrate.

In the laminate inlay in accordance with the invention for a laminate structure that is formed from multiple laminate layers, the transponder layer, on its antenna side, is equipped with an upper cover layer, which, in an overlapping region with the chip, is arranged on a rear side of the semiconductor body of the chip.

In this way, a laminate inlay is proposed, which can in particular be used as a semi-finished product when producing chip cards and which already allows for the protected arrangement both of the antenna and of the chip, in a laminate structure having only two laminate layers.

If the upper cover layer is arranged both on the rear side of the semiconductor body of the chip and on the contact pads, due to the upper cover layer, a sheathing that stabilizes the chip in a special manner is the result.

A stabilizing effect for the entire laminate inlay can be achieved if the upper cover layer is arranged both on the rear side of the semiconductor body of the chip and on the carrier substrate of the contact pads.

Alternatively, in particular if use of a carrier substrate for the contact pads is omitted, the upper cover layer can be arranged both on the rear side of the semiconductor body of the chip and on the terminal ends of the wire conductor of the antenna, in order to achieve a comparably stabilizing effect.

The chip card in accordance with the invention has the features of claim 13. Said chip card is already embodied by the laminate inlay itself in a minimum configuration.

In a special embodiment, the chip card can additionally have an upper external layer which is directly arranged on the upper cover layer of the laminate inlay, and which can be embodied as a functional layer or also as a laminate layer having a special, in particular an individualizing marking of the chip card.

Alternatively to the chip card that is equipped with an upper external layer, the chip card can be equipped with a lower external layer on the rear side of the antenna substrate, wherein said lower external layer can also be arranged, in an additional way to the upper external layer, on the laminate inlay of the chip card.

Even if, in accordance with an embodiment of the chip card, apart from the upper external layer, a lower external layer is provided, a chip card that is designed in such an individual way is still characterized by a laminate structure having the smallest possible number of laminate layers.

In a first variant of the method in accordance with the invention for producing a transponder layer, the following steps are executed:
providing an antenna substrate having an antenna that is arranged on an antenna side of the antenna substrate and that is formed from a wire conductor, having terminal ends of the wire conductor, said terminal ends extending on the antenna side of the antenna substrate at a distance from each other;
arranging contact pads on the terminal ends of the wire conductor, in such a manner that the contact pads respectively extend on a terminal end with an antenna contact portion and on the antenna side of the antenna substrate with a chip contact portion;
contacting the antenna contact portions of the contact pads with the terminal ends of the wire conductor;
arranging the chip in a chip accommodating region of the antenna substrate, said chip accommodating region being formed adjacently to the terminal ends, in such a manner that chip terminals that are arranged on a contact side of the semiconductor body of the chip are respectively arranged on a chip contact portion of the contact pads; as well as
contacting the chip terminals with the chip contact portions of the contact pads.

Arranging the contact pads on the terminal ends of the wire conductor is simplified if a carrier substrate that is equipped with the contact pads is positioned on the antenna side of the antenna substrate in such a manner that the antenna contact portions of the contact pads come to abut against the terminal ends of the wire conductor with their antenna contact side that faces towards the antenna substrate.

The contact pads can basically be contacted with the terminal ends of the wire conductor in all known manners, wherein, for configuring the contacting, a heat and/or pressure treatment of the contact pads at the rear has particularly proven itself, since this type of contacting, subject to a corresponding selection of the material for the contact pads, allows for carrying out the contacting without feeding in additional contact material and only by melting the contact pads at least on the surface.

Pressurizing the contact pads at the rear by means of an ultrasonic plunger is particularly advantageous, such that the ultrasonic tool, apart from introducing the required contacting energy, also allows for precise contact positioning of the contact pads on the terminal ends of the wire conductor.

In particular in the case of the contact pads being arranged on their own carrier substrate, it is advantageous if, for contacting the contact pads with the terminal ends of the wire conductor, the carrier substrate is fixed on the antenna substrate, such that the contact pads can be exactly positioned by means of the carrier substrate, even if there is no direct influence on the contact pads themselves, in order to carry out a contacting, at a precise position, of the contact pads with a contactless energy introduction method, for example by means of a laser treatment.

If, for contacting the chip terminals of the chip with the chip contact regions of the contact pads, the chip is positioned on the contact pads with its chip terminals that are placed against the chip contact sides of the contact pads, arranging the chip on the antenna side of the antenna substrate having the smallest possible gap formation between the contact side of the semiconductor body of the chip, the contact side being equipped with the chip terminals, and the antenna side of the antenna substrate is possible, such that a correspondingly small height of the transponder layer can be achieved.

Carrying out contacting of the chip terminals with the contact pads by means of a pressure and heat energy treatment of the semiconductor body of the chip at the rear allows for contacting at a precise position with small energy expenditure.

Since the number of the required method steps for producing a transponder layer is reduced thereby, it proves to be particularly advantageous if contacting the contact pads with the terminal ends of the wire conductor is effected simultaneously with contacting the chip terminals with the contact pads.

In an alternative variant of the method in accordance with the invention, the following steps are executed:
providing an antenna substrate that is equipped with substrate recesses;
arranging contact pads in the substrate recesses of the antenna substrate, in such a manner that contact sides of the contact pads are arranged at an antenna side of the antenna substrate;
arranging an antenna that is formed from a wire conductor on the antenna side of the antenna substrate, in such a manner that terminal ends of the wire conductor are arranged on the contact sides of the contact pads;
contacting the terminal ends of the wire conductor with the contact sides of the contact pads;
arranging the chip in a chip accommodating region that is embodied adjacently to the terminal ends of the wire conductor on the antenna side of the antenna substrate, in such a manner that the chip is caused to abut against the contact sides of the contact pads with its chip terminals that are oriented against the antenna side of the antenna substrate; as well as
contacting the chip terminals with the contact pads.

This variant of the method allows for the production of a transponder layer based on an antenna substrate that is only equipped with recesses.

In a further variant of the method in accordance with the invention, the following steps are executed:
providing an antenna substrate having an antenna that is arranged on an antenna side of the antenna substrate and that is formed from a wire conductor, having terminal ends of the wire conductor, said terminal ends extending over substrate recesses in the antenna substrate;
arranging contact pads in the substrate recesses of the antenna substrate, in such a manner that the contact pads, with their contact sides that face towards the terminal ends of the wire conductor, are caused to abut against the terminal ends, starting from a bottom side of the antenna substrate, said bottom side being opposite to the antenna side of the antenna substrate;
contacting the terminal ends of the wire conductor on the contact sides of the contact pads;
arranging the chip in a chip accommodating region that is formed on the antenna side of the antenna substrate, adjacently to the terminal ends of the wire conductor, in such a manner that the chip is caused to abut against the contact sides of the contact pads with its chip terminals that are oriented against the antenna side of the antenna substrate; as well as
contacting the chip terminals with the contact pads.

In this particularly advantageous variant, the terminal ends of the wire conductors of the antenna, said terminal ends having been applied to the antenna side of the antenna substrate before arranging the contact pads in the substrate recesses, can be used as positioning stops for arranging the contact pads.

If contacting the terminal ends of the wire conductor of the antenna with the contact pads is effected simultaneously with contacting the chip terminals with the contact pads, the number of method steps that is required for producing the transponder layer can be reduced.

In the following, with the aid of the drawing, advantageous embodiments of the transponder layer and of the methods that are utilized for producing a transponder layer are explained.

In the figures:

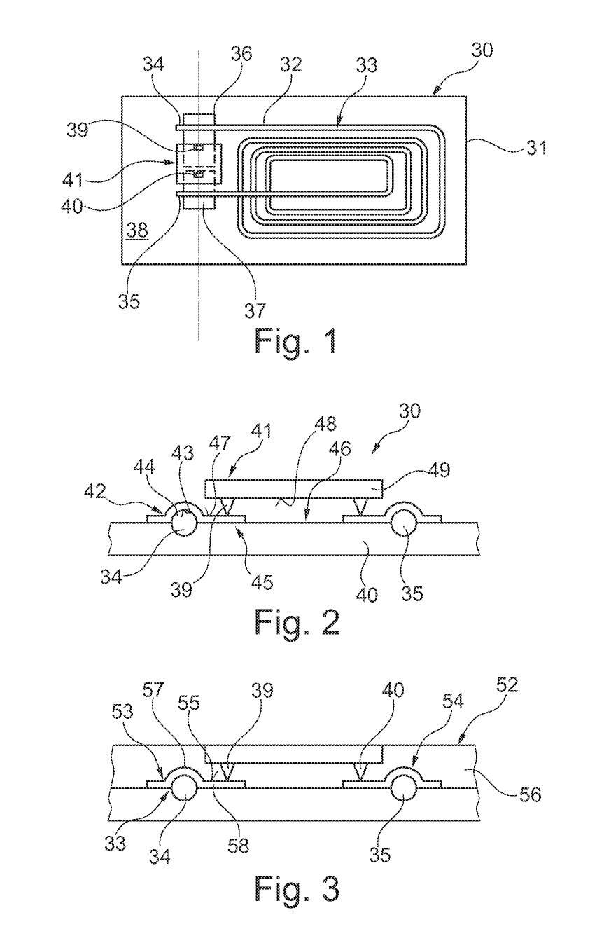

FIG. 1 shows a first embodiment of a transponder layer in a top view;

FIG. 2 shows a sectional illustration of the transponder layer that is illustrated in FIG. 1 in accordance with sectional line II-II in FIG. 1;

FIG. 3 shows a sectional illustration of a further embodiment of the transponder layer;

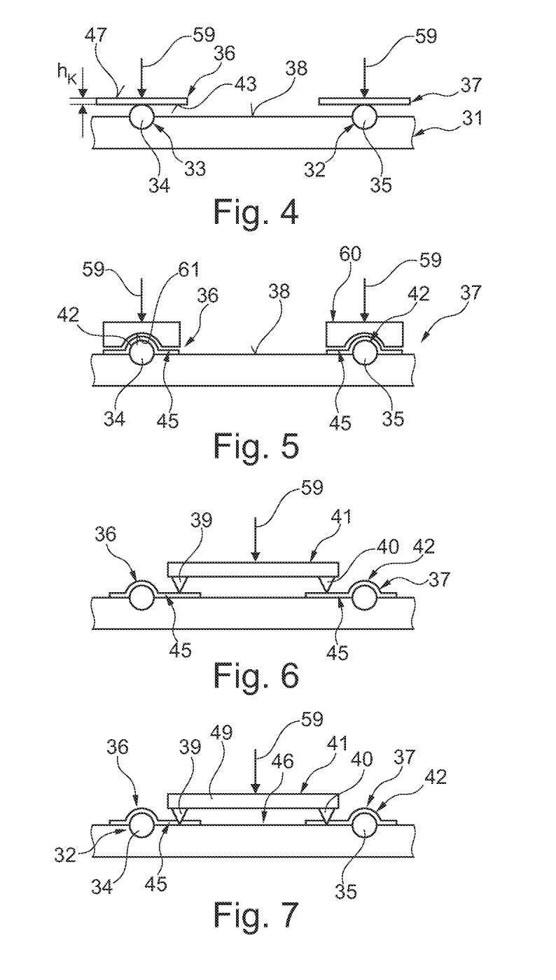

FIGS. 4-7 show a sequence of different method steps for producing the transponder layer that is illustrated in FIGS. 1 and 2;

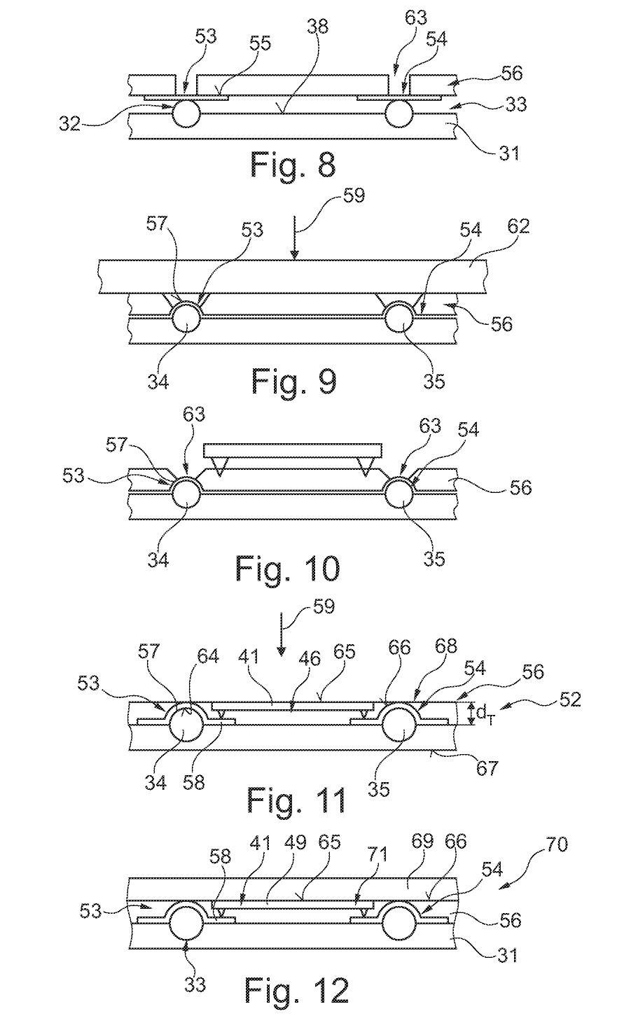

FIGS. 8-11 show a sequence of the production steps for producing the transponder layer that is illustrated in FIG. 3 in cross-section;

FIG. 12 shows a laminate inlay that has been produced on the basis of the transponder layer that is illustrated in FIG. 11;

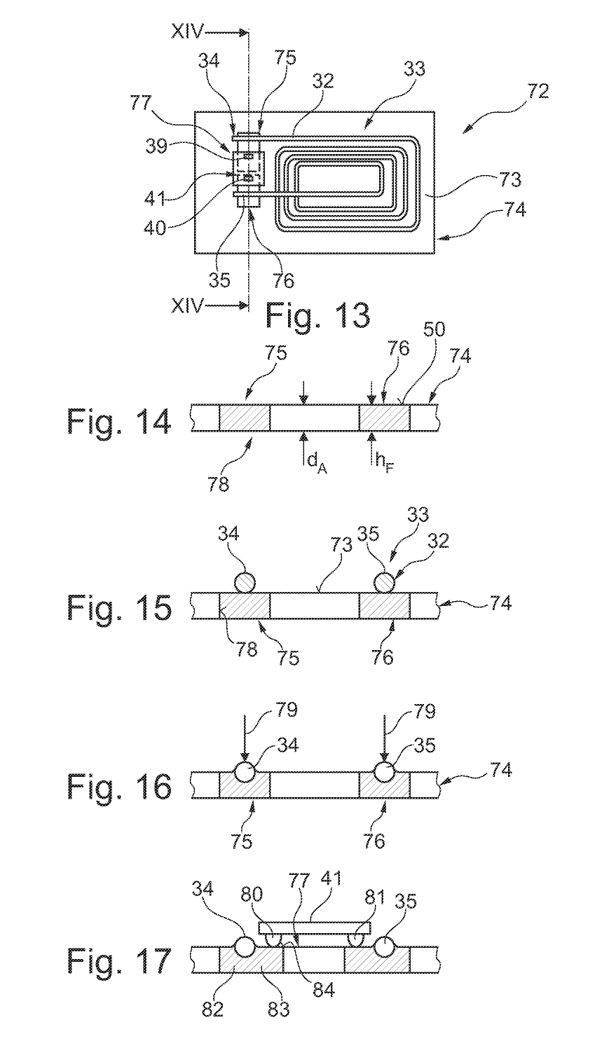

FIG. 13 shows a further embodiment of a transponder layer in a top view;

FIGS. 14-18 show a sequence of method steps for producing the transponder layer that is illustrated in FIG. 13;

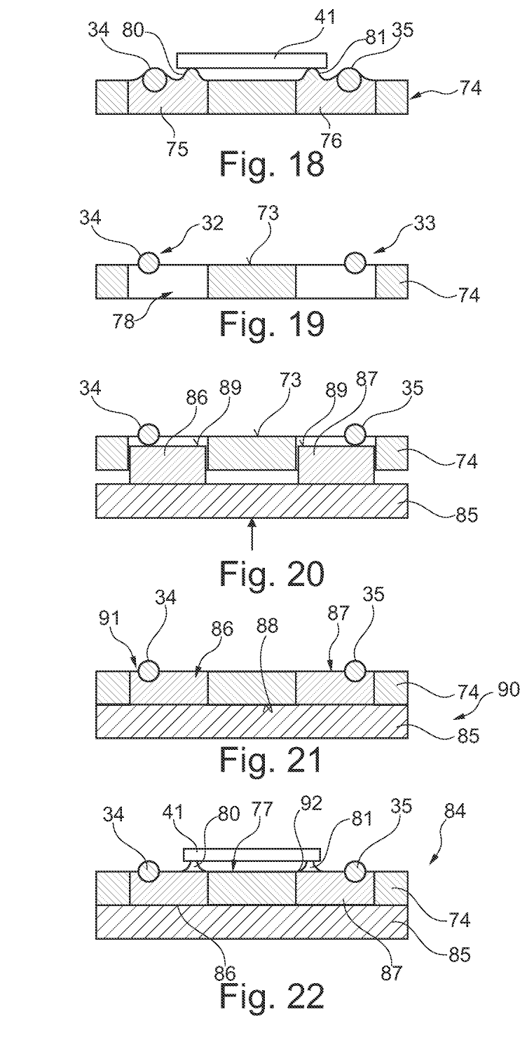

FIGS. 19-22 show a sequence of method steps for producing a further embodiment of a transponder layer.

FIG. 1 shows a transponder layer 30 having an antenna substrate 31, on which an antenna 33 that is formed from a wire conductor 32 is arranged. The antenna 33, via terminal ends 34, 35 of the wire conductor 32, is in each instance contacted with one terminal conductor which is embodied as a contact pad 36, 37, and which extends on an antenna side 38 of the antenna substrate 31 and simultaneously serves for contacting with chip terminals 39, 40 of a chip 41.

As it can be taken from the sectional illustration in accordance with FIG. 2, the contact pads 36, 37 extend over the terminal ends 34, 35 of the wire conductor 32 with an antenna contact portion 42, wherein, in each instance, one antenna contact side 43 of the contact pads 36, 37 abuts against a cross-section 44 of the wire conductor 32, fitting tightly against the same. Adjoining the antenna contact portion 42, the contact pads 36, 37 in each instance have one chip contact portion 45, which extends into a chip accommodating region 46 being embodied between the terminal ends 34, 35 on the antenna side 38 of the antenna substrate 31.

In the region of the chip contact portions 45, the contact pads 36, 37, on their chip contact side 47 that is opposed to the antenna contact side 43, are contacted in each instance with one chip terminal 39, 40 that is arranged on a contact side 48 of a semiconductor body 49 of the chip 41.

In the contacting that is illustrated in FIG. 2 by way of example, between the chip terminals 39, 40 of the chip 41 and the contact pads 36, 37, an electrically conductive connection is established in that the chip terminals 39, 40 that are embodied as profiled penetrators, for instance wedge-shaped or cone-shaped penetrators, in the exemplary embodiment are pressed into the chip contact portion 45, such that, additionally to a positive connection being produced between the chip terminals 39, 40 and the chip contact portions 45 of the contact pads 36, 37, simultaneously, when producing the connection or while the chip terminals 39, 40 penetrate the contact pads 36, 37, any oxide layers that might be present on the chip contact side 47 of the contact pads 36, 37 are broken up.

Fixing the connection between the chip terminals 39, 40 and the contact pads 36, 37 can, for example, be effected by later melting the chip terminals 39, 40 and/or the contact pads 36, 37, at least partially. By means of the above-mentioned partial melting, the electrically conductive connection between the antenna contact portions 42 of the contact pads 36, 37 and the terminal ends 34, 35 of the wire conductor 32 that forms the antenna 33 can also be established.

FIG. 3 shows, in an illustration that corresponds to FIG. 2, a transponder layer 52, which differs from the transponder layer 30 that is illustrated in FIG. 2 to the extent that contact pads 53, 54 serve for contacting the terminal ends 34, 35 of the wire conductor 32 that forms the antenna 33 with the chip terminals 39, 40 of the chip 41, said contact pads being arranged on a carrier substrate 56 with their chip contact side 55. Apart from that, the contact pads 53, 54, in conformity with the contact pads 36, 37 of the transponder layer 30 that is illustrated in FIG. 2, are contacted with the terminal ends 34, 35 of the wire conductor 32 in the region of their antenna contact portion 57 and with the chip terminals 39, 40 of the chip 41 in the region of their chip contact portion 58 that adjoins the antenna contact portion 57.

As it can be seen from the sequence of the method steps for producing the transponder layer 30 that is illustrated in FIG. 2, the sequence being illustrated in FIGS. 4 to 7, in the illustrated method variant, starting from providing the antenna substrate 31 having the antenna 33 that is already arranged on the antenna side 38 of the antenna substrate 31 and that is formed from the wire conductor 32, the contact pads 36, 37 are initially arranged, said contact pads having an extension that is substantially planar and having a relatively small height h_{K} in comparison to the area of the antenna contact side 43 that faces towards the terminal ends 34, 35 of the wire conductor 32 or to the area of the chip contact side 47 that is opposed to the antenna contact side 43. After feeding in the contact pads 36, 37 against the terminal ends 34, 35, in the feeding direction 59, the contact pads 36, 37, as it is illustrated in FIG. 5, are deformed by means of a forming tool 60, which is moved up against the contact pads 36, 37 in the feeding direction 59, in this process causing the contact pads 36, 37 to fit tightly against the terminal ends 34, 35 of the wire conductor 32 in the region of their antenna contact portions 42, owing to a dent 61 that is embodied in the forming tool 60.

If the contact pads 36, 37 are treated by the forming tool 60 while the forming tool 60 is simultaneously heated, a material connection between the contact pads 36, 37 and the terminal ends 34, 35 can be produced, subject to a suitable selection of the material for the contact pads 36, 37 or to a suitable coating of the antenna contact side 43 of the contact pads 36, 37.

FIG. 6 shows the application of the chip 41 in the feeding direction 59 in the chip accommodating region 46 between the terminal ends 34, 35 of the wire conductor 32, in such a manner that the chip terminals 39, 40 of the chip 41 are caused to abut against the chip contact portions 45 of the contact pads 36, 37. Subsequently, caused by treating the semiconductor body 49 of the chip 41 with pressure and heat energy at the rear, the chip terminals 39, 40 can penetrate the chip contact portions 45 of the contact pads 36, 37, while the chip terminals 39, 40 and/or the chip contact portions 45 of the contact pads 36, 37 are simultaneously partially melted for producing a material connection between the chip terminals 39, 40 and the contact pads 36, 37.

FIGS. 8 to 11 illustrate a possible variant of a method for producing the transponder layer 52 that is illustrated in FIG. 3, wherein the contact pads 53, 54, which are arranged on the carrier substrate 56 with their chip contact side 55, are again applied, starting from an antenna 33 that has already been arranged on the antenna side 38 of the antenna substrate 31. Owing to the arrangement of the contact pads 53, 54 on the carrier substrate 56, said contact pads can, for example, be formed from an electrically conductive coating of the carrier substrate 56, which means for example by a coating that has been applied using printing technology.

As FIG. 9 shows, arranging the antenna contact portion 57 of the contact pads 53, 54 on the terminal ends 34, 35 in such a way that they fit tightly against the latter can be achieved in that the carrier substrate 56, in the feeding direction 59, is treated with pressure at the rear by means of a pressure plate 62.

As it can be seen in FIGS. 8 to 10, in the case of the illustrated exemplary embodiment, the carrier substrate 56 is equipped with recesses 63 in the region of the antenna contact portions 57 of the contact pads 53, 54, said recesses allowing for a heat energy treatment of the contact pads 53, 54 at the rear after fitting the antenna contact portions 57 tightly against the terminal ends 34, 35, in order to allow for a material connection, by partial melting, between the contact pads 53, 54 and the terminal ends 34, 35, subject to a corresponding selection of the material for the contact pads 53, 54 or to a suitable coating of the antenna contact sides 64 of the contact pads 53, 54.

As FIG. 10 shows, the chip 41 can subsequently be placed in the chip accommodating region 46 between the terminal ends 34, 35, wherein the chip terminals 39, 40 of the chip 41 penetrate the carrier substrate 56 and finally, as it is illustrated in FIG. 11, penetrate chip contact portions 58, subject to the semiconductor body 49 of the chip 41 being constantly pressurized in the feeding direction 59, and can establish a material connection to the contact pads 53, 54, as it has already been explained with the aid of FIG. 7 concerning the transponder layer 30.

As it becomes apparent from the figure sequence of FIGS. 10 and 11, subject to a suitable dimensioning or to a suitable thickness d_{T} and selection of the plastic material of the carrier substrate 56, contacting the chip 41 with the contact pads 53, 54 can be effected simultaneously with embedding the chip 41 into the carrier substrate 56, such that the semiconductor body 49 of the chip 41, as it is illustrated in FIG. 11, is accommodated with its rear side 65 in a substantially flush way in a rear side 66 of the carrier substrate 56, after the chip 41 has been contacted with the contact pads 53, 54. In this way, the transponder layer 52 has an upper transponder side 68 that is embodied so as to be parallel to a bottom side 67 of the antenna substrate 31 and so as to be planar.

FIG. 12 shows that, based on the transponder layer 52 that is illustrated in FIG. 11, by simply adding an upper cover layer 69 on the upper transponder side 68, a laminate inlay 70 can be formed, which has a transponder 71 that is accommodated in a laminate structure comprising the antenna substrate 31, the carrier substrate 56 and the cover layer 69 and that is hermetically sealed to the outside, having a chip 41 that is contacted with the antenna 33 via the contact pads 53, 54.

FIG. 13 shows a transponder layer 72, having an antenna 33 which is arranged on an antenna side 73 of an antenna substrate 74 and which is formed from a wire conductor 32, and which is connected to contact pads 75, 76 via terminal ends 34, 35 of the wire conductor 32 in an electrically conductive way. The contact pads 75, 76 are arranged in the antenna substrate 74 and extend into a chip accommodating region 77 which is embodied between the terminal ends 34, 35 of the wire conductor 32 on the antenna side 73, and which is arranged in the chip 41 and is connected in an electrically conductive way to the contact pads 75, 76 via chip terminals 39, 40.

FIGS. 14 to 18, in accordance with a possible variant, illustrate the sequence of method steps for producing the transponder layer 72 that is illustrated in FIG. 13.

As FIG. 14 shows, in which the antenna substrate 74 is illustrated in a sectional view in accordance with sectional line XIV-XIV, in the illustrated method variant, the antenna substrate 74 is the starting point, said antenna substrate being equipped with the contact pads 75, 76 in substrate recesses 78, the contact pads filling the substrate recesses 78 as packings. The contact pads 75, 76, with respect to their height h_{F}, therefore are substantially in conformity with the thickness d_{A} of the antenna substrate 74, such that contact sides 50 of the contact pads 75, 76 are substantially arranged at the surface of the antenna contact side 73 of the antenna substrate 74.

In the following, the antenna 33 can be formed by arranging or laying the wire conductor 32 on the antenna side 73 of the antenna substrate 74, in such a manner that the terminal ends 34, 35 of the wire conductor 32 extend over the contact pads 75, 76 that are accommodated in the substrate recesses 78 of the antenna substrate 74, as it is illustrated in FIG. 15.

Due to a treatment 79 of the terminal ends 34, 35 with pressure and heat energy, a material connection can be produced between the terminal ends 34, 35 and the contact pads 75, 76, the result being that the terminal ends 34, 35 are at least partially embedded into the contact pads 75, 76, wherein said embedding of the terminal ends 34, 35 into the contact pads 75, 76 can also be effected simultaneously with arranging the wire conductor 32 for forming the antenna 33 using laying technique.

FIG. 17 shows the following arrangement of the chip 41 in the chip accommodating region 77, wherein chip terminals 80, 81, in the vicinity of an antenna contact portion 82 of the contact pads 75, 76, are caused to abut against a contact side 89 of the contact pads 75, 76, in a chip contact portion 83 of the contact pads 75, 76.

In the exemplary embodiment that is illustrated in FIG. 17, the chip terminals 80, 81 are, in a way that deviates from the exemplary embodiment of the chip terminals 39, 40 that is, for example, illustrated in FIGS. 6 and 7, not embodied as penetrators so as to be profiled, but rather as contact elevations (bumps), which allow for a connection to the contact pads 75, 76 by partial melting, such that a material connection, as it is illustrated in FIG. 18, has been produced between the chip terminals 80, 81 and the contact pads 75, 76 after melting of the chip terminals 80, 81.

As FIGS. 19 to 22 show, a transponder layer 84 that has been modified as compared to the transponder layer 72 that is illustrated in FIG. 13, said transponder layer 84 being shown in FIG. 22, can be produced in that, starting from the antenna 33 that has already been arranged on the antenna side 73 of the antenna substrate 74, the antenna having terminal ends 34, 35 of the wire conductor 32, said terminal ends extending over the substrate recesses 78, contact pads 86, 87 are arranged in the substrate recess 78.

Hereunto, as it is illustrated in FIG. 20, a carrier substrate 85, on which contact pads 86, 87 are arranged, is arranged on a bottom side 88 of the antenna substrate 74 and, in this process, has been introduced into the substrate recesses 78 with the contact pads 86, 87, in such a manner that contact sides 89 of the contact pads 86, 87, said contact sides facing towards the terminal ends 34, 35, are caused to abut against the terminal ends 34, 35.

Subsequently, the antenna substrate 74 and the carrier substrate 85 are pressed against each other under the effect of pressure and of a temperature, such that an antenna laminate 90 is created corresponding to the illustration in FIG. 21, wherein the terminal ends 34, 35 of the wire conductor 32, in the region of antenna contact portions 91, are embedded into the contact pads 86, 87 and establish a material connection to the same.

FIG. 22 finally shows, analogously to the illustration that has previously been discussed in FIG. 18, concerning the production of the transponder layer 72, the chip 41 that is arranged in the chip accommodating region 77 between the terminal ends 34, 35 and that establishes, in the region of chip contact portions 92, a material connection to the contact pads 86, 87 via its chip terminals 80, 81.

1. A transponder layer for producing a laminate structure embodied as a chip card, said transponder layer comprising:
an antenna substrate having an antenna side;
an antenna formed from a wire conductor disposed on said antenna side, said wire conductor including terminal ends; and
a chip having terminal conductors connecting the chip to the wire conductor of the antenna, said chip being arranged adjacent to said terminal ends of the wire conductor such that the terminal ends of the wire conductor and the chip terminals are arranged on a contact side of a semiconductor of the chip, the contact side facing towards the antenna substrate, and each terminal end being connected with at least one of the terminal conductors.

2. The transponder layer according to claim 1, in which the chip is arranged between the terminal ends of the wire conductor.

3. The transponder layer according to claim 1, in which the terminal conductors connecting the chip to the wire conductor of the antenna are contact pads arranged on the antenna side in such a manner that the contact pads, for being contacted with the antenna, have an antenna contact portion having an antenna contact side facing towards the antenna side and, for being contacted with the chip, have a chip contact portion having a chip contact side that is opposite to the antenna contact side and faces away from the antenna side.

4. The transponder layer according to claim 3, in which the contact pads fit tightly against the wire conductor of the antenna with their antenna contact side.

5. The transponder layer according to claim 3, in which the contact pads, are arranged on a carrier substrate and the chip terminals extend through the carrier substrate.

6. The transponder layer according to claim 1, in which the terminal conductors for connecting the chip to the wire conductor of the antenna are contact pads arranged in the antenna substrate and have a contact side, which serves both for contacting with the antenna and for contacting with the chip, said contact pads are arranged at a surface of the antenna side of the antenna substrate.

7. The transponder layer according to claim 6, in which the contact pads packings, which fill substrate recesses in the antenna substrate.

8. The transponder layer according to claim 7, in which the contact pads are arranged on a carrier substrate arranged on a bottom side of the antenna substrate, the bottom side being opposite to the antenna side of the antenna substrate, in such a manner that contact sides formed by surfaces of the contact pads are arranged at the surface of the antenna side of the antenna substrate.

9. A laminate inlay for a laminate structure formed from multiple laminate layers and having a transponder layer according to claim 1, in which the transponder layer, on its antenna side, is equipped with an upper cover layer, which, in an overlapping region with the chip, is arranged on a rear side of the semiconductor body of the chip.

10. The laminate inlay according to claim 9, in which the upper cover layer is arranged both on the rear side of the semiconductor body of the chip and on the terminal conductors in the form of contact pads.

11. The laminate inlay according to claim 9, in which the upper cover layer is arranged both on the rear side of the semiconductor body of the chip and on a rear side of the carrier substrate of the terminal conductors in the form of contact pads.

12. The laminate inlay according to claim 9, in which the upper cover layer is arranged both on the rear side of the semiconductor body of the chip and on the terminal ends of the wire conductor of the antenna.

13. A chip card having a laminate inlay according to claim 9.

14. The chip card according to claim 13, in which an upper external layer is directly arranged on the upper cover layer.

15. The chip card according to claim 13, in which a lower external layer is arranged on the rear side of the antenna substrate.

16. A method for producing a transponder layer according to claim 1, said method comprising:
providing an antenna substrate having an antenna arranged on an antenna side of the antenna substrate and formed from a wire conductor, having terminal ends, said terminal ends extending on the antenna side of the antenna substrate at a distance from each other;
arranging contact pads on the terminal ends of the wire conductor, in such a manner that the contact pads respectively extend on a terminal end with an antenna contact portion, and on the antenna side of the antenna substrate with a chip contact portion;
contacting the antenna contact portions of the contact pads with the terminal ends of the wire conductor;
arranging the chip in a chip accommodating region of the antenna substrate, said chip accommodating region being formed adjacently to the terminal ends, in such a manner that chip terminals that are arranged on a contact side of a semiconductor body of the chip are respectively arranged on a chip contact portion of the contact pads; and
contacting the chip terminals with the chip contact portions of the contact pads.

17. The method according to claim 16, in which for arranging the contact pads on the terminal ends of the wire conductor, a carrier substrate equipped with the contact pads is positioned on the antenna side of the antenna substrate in such a manner that the antenna contact portions of the contact pads abut against the terminal ends of the wire conductor with antenna contact sides facing towards the antenna substrate.

18. The method according to claim 16, in which the contact pads, for being contacted with the terminal ends of the wire conductor, are treated with heat and/or pressure at a rear of said contact pads.

19. The method according to claim 18, in which the contact pads are treated with pressure using an ultrasonic plunger.

20. The method according to claim 17, in which, for contacting the contact pads with the terminal ends of the wire conductor, the carrier substrate is fixed on the antenna substrate.

21. A method for producing a transponder layer according to claim 1, said method comprising:
providing an antenna substrate that is equipped with substrate recesses;
arranging contact pads in the substrate recesses of the antenna substrate, in such a manner that contact sides of the contact pads are arranged at the surface of an antenna side of the antenna substrate;
arranging an antenna formed from a wire conductor on the antenna side of the antenna substrate, in such a manner that terminal ends of the wire conductor are arranged on the contact sides of the contact pads;
contacting the terminal ends of the wire conductor with the contact sides of the contact pads;
arranging the chip in a chip accommodating region formed adjacent to the terminal ends of the wire conductor on the antenna side of the antenna substrate, in such a manner that the chip abuts against the contact sides of the contact pads with its chip terminals oriented against the antenna side of the antenna substrate; and
contacting the chip terminals with the contact pads.

22. A method for producing a transponder layer according to claim 1, said method comprising:
providing an antenna substrate having an antenna arranged on an antenna side of the antenna substrate and formed from a wire conductor, having terminal ends of the wire conductor, said terminal ends extending over substrate recesses in the antenna substrate;
arranging contact pads in the substrate recesses of the antenna substrate, in such a manner that the contact pads, with their contact sides that face towards the terminal ends of the wire conductor, abut against the terminal ends, starting from a bottom side of the antenna substrate, said bottom side being opposite to the antenna side of the antenna substrate;
contacting the terminal ends of the wire conductor on the contact sides of the contact pads;
arranging the chip in a chip accommodating region formed on the antenna side of the antenna substrate, adjacently to the terminal ends of the wire conductor, in such a manner that the chip abuts against the contact sides of the contact pads with its chip terminals oriented against the antenna side of the antenna substrate; and
contacting the chip terminals with the contact pads.

23. The method according to claim 16, in which the chip terminals are contacted with the contact pads by treating the chip with pressure and with a temperature at a rear of the chip.

24. The method according to claim 16, in which contacting the terminal ends of the wire conductor of the antenna with the contact pads is effected simultaneously with contacting the chip terminals with the contact pads.
